(19) United States
(12) Patent Application Publication
(10) Pub. No.: US 2026/0026370 A1
(43) Pub. Date: Jan. 22, 2026

(54) SEMICONDUCTOR PACKAGE WITH STACKED STRUCTURE

(71) Applicant: Samsung Electronics Co., Ltd., Suwon-si (KR)

(72) Inventor: Hyeonjeong HWANG, Suwon-si (KR)

(73) Assignee: Samsung Electronics Co., Ltd., Suwon-si (KR)

(21) Appl. No.: 19/065,746

(22) Filed: Feb. 27, 2025

(30) Foreign Application Priority Data
Jul. 17, 2024 (KR) 10-2024-0094361

(51) Int. Cl. H01L 23/00; H01L 23/31; H01L 25/07

(52) U.S. Cl. CPC H01L 24/24; H01L 24/32; H01L 24/73; H01L 25/071; H01L 23/3107; H01L 2224/24137; H01L 2224/244; H01L 2224/32145; H01L 2224/32225; H01L 2224/73217; H01L 2224/73267; H01L 2225/06562

(57) ABSTRACT

A semiconductor package includes: a support substrate; a first semiconductor chip on the support substrate, the first semiconductor chip including one or more first chip pads; a second semiconductor chip spaced apart from the first semiconductor chip, the second semiconductor chip including one or more second chip pads; a third semiconductor chip on the first semiconductor chip and the second semiconductor chip, the third semiconductor chip comprising one or more third chip pads; one or more first conductive structures on the one or more first chip pads; one or more second conductive structures on the one or more second chip pads; and a redistribution layer on the one or more first conductive structures, the one or more second conductive structures, and the one or more third chip pads.

### CROSS-REFERENCE TO RELATED APPLICATIONS

This U.S. non-provisional patent application claims priority under 35 U.S.C. § 119 of Korean Patent Application No. 10-2024-0094361, filed on Jul. 17, 2024, the entire contents of which are hereby incorporated by reference.

### BACKGROUND

The present disclosure herein relates to a semiconductor package with a stacked structure.

An integrated circuit chip is packaged into a semiconductor package to have a suitable form to be installed in an electronic device. In a semiconductor package, a semiconductor chip is mounted on a printed circuit board, and the semiconductor chip and the printed circuit board are electrically connected to each other using bonding metal wires or bumps. Current semiconductor packages are unstable due to the large size of these semiconductor packages. With the development of electronics industry, various researches are carried out to improve the reliability and reduce the size of semiconductor packages.

### SUMMARY

The present disclosure provides a structure of a semiconductor package having improved reliability and a method for manufacturing the same.

According to one or more embodiments, a semiconductor package includes: a support substrate; a first semiconductor chip on the support substrate, the first semiconductor chip including one or more first chip pads; a second semiconductor chip spaced apart from the first semiconductor chip in a first direction parallel with a surface of the support substrate, the second semiconductor chip including one or more second chip pads; a third semiconductor chip on the first semiconductor chip and the second semiconductor chip, the third semiconductor chip including one or more third chip pads; one or more first conductive structures on the one or more first chip pads, the one or more first conductive structures extending in a second direction perpendicular to the first direction; one or more second conductive structures on the one or more second chip pads, the one or more second conductive structures extending in the second direction; and a redistribution layer on the one or more first conductive structures, the one or more second conductive structures, and the one or more third chip pads, wherein the one or more first conductive structures and the one or more second conductive structures are spaced apart from each other in the first direction with the third semiconductor chip therebetween, and a number of the one or more first chip pads, a number of the one or more second chip pads, and a number of the one or more third chip pads are the same.

According to one or more embodiments, a semiconductor package includes: a first semiconductor chip; a second semiconductor chip spaced apart from the first semiconductor chip in a first direction; a third semiconductor chip on the first semiconductor chip and the second semiconductor chip; a first conductive structure on the first semiconductor chip, the first conductive structure extending in a second direction perpendicular to the first direction; and a second conductive structure on the second semiconductor chip, the second conductive structure extending in the second direction, wherein, in a plan view, the first semiconductor chip and the second semiconductor chip are positioned along the first direction such that the first semiconductor chip is rotated 180 degrees along the first direction with respect to the second semiconductor chip, and the third semiconductor chip is positioned on the first semiconductor chip and the second semiconductor chip such that the third semiconductor chip is rotated 90 degrees along the second direction with respect to the first semiconductor chip.

According to one or more embodiments, a semiconductor package includes: a first semiconductor package; and a second semiconductor package on the first semiconductor package, wherein the first semiconductor package includes: a first redistribution layer; a first semiconductor chip on the first redistribution layer; a second redistribution layer on the first semiconductor chip; and a first conductive structure between the first redistribution layer and the second redistribution layer, the first conductive structure extending in a first direction, and the second semiconductor package includes: a support substrate; a plurality of semiconductor chips stacked on the support substrate; and a third redistribution layer spaced apart from the support substrate with the plurality of second semiconductor chips therebetween, wherein each of the plurality of semiconductor chips stacked on the support substrate include: a second semiconductor chip and a third semiconductor chip spaced apart from each other in a second direction parallel with a surface of the support substrate and perpendicular to the first direction; and a fourth semiconductor chip on the second semiconductor chip and the third semiconductor chip, and wherein the third redistribution layer comprises a redistribution pattern wherein a chip pad of the fourth semiconductor chip is in direct contact with the redistribution pattern wherein the semiconductor package further comprises one or more second conductive structures on the second semiconductor chip and the third semiconductor chip, and wherein the fourth semiconductor chip is a memory chip.

### BRIEF DESCRIPTION OF DRWINGS

The accompanying drawings are included to provide a further understanding of the embodiments of the present disclosure, and are incorporated in and constitute a part of this specification. The drawings illustrate embodiments of the present disclosure and, together with the description, serve to explain principles of the embodiments of the present disclosure. In the drawings:

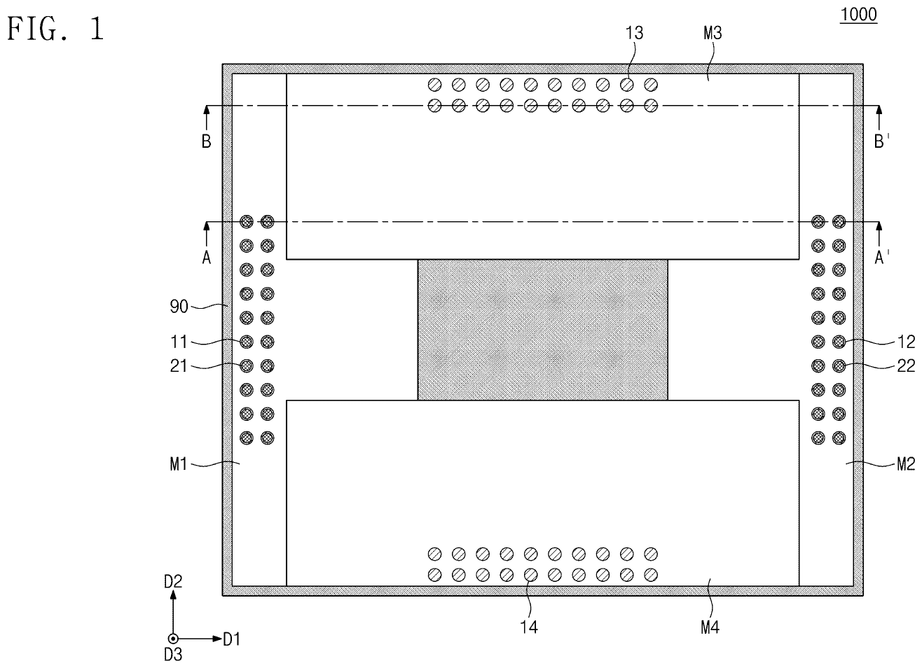

FIG. 1 is a plan view of a semiconductor package according to some embodiments of the present disclosure;

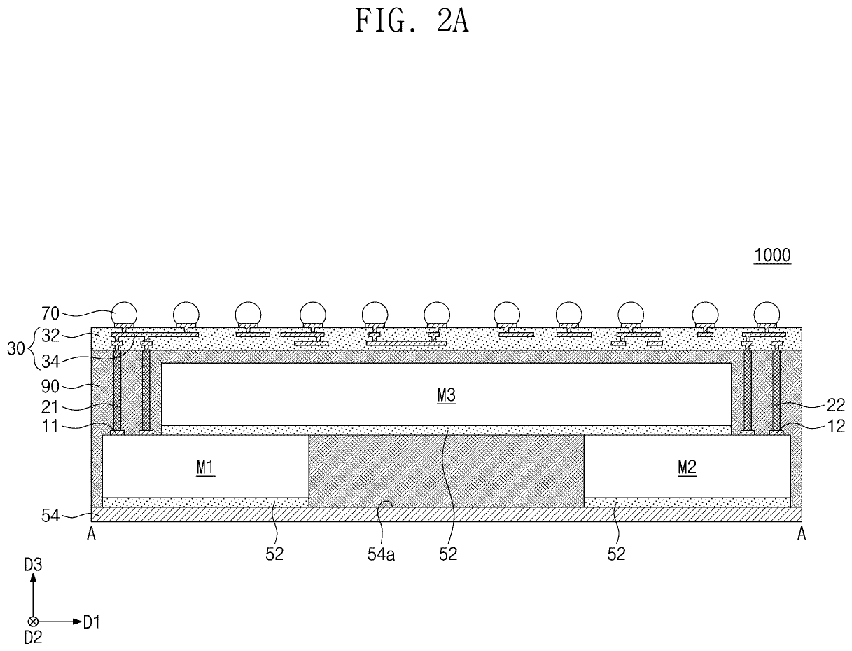

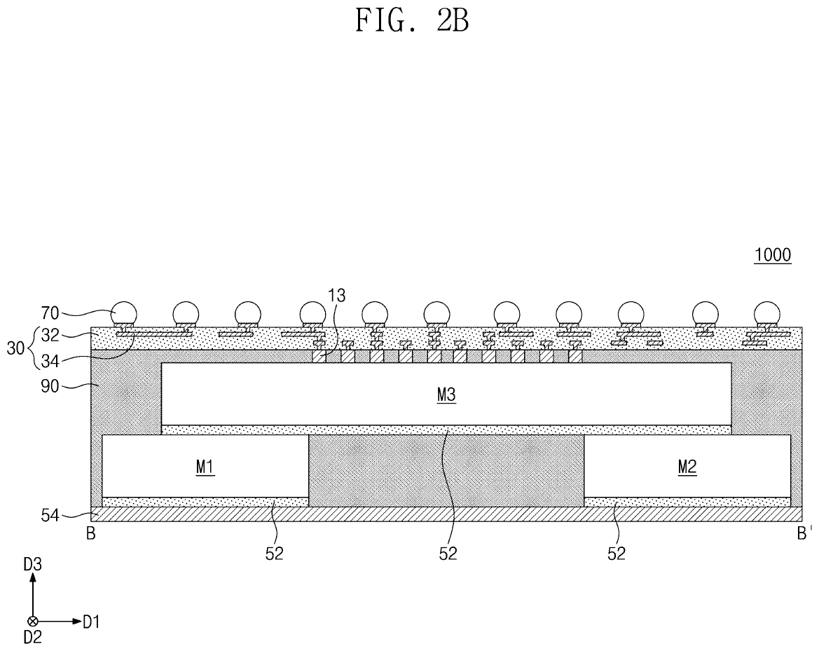

FIG. 2A is a cross-sectional view taken along line A-A′ of FIG. 1 according to some embodiments of the present disclosure;

FIG. 2B is a cross-sectional view taken along line B-B′ of FIG. 1 according to some embodiments of the present disclosure;

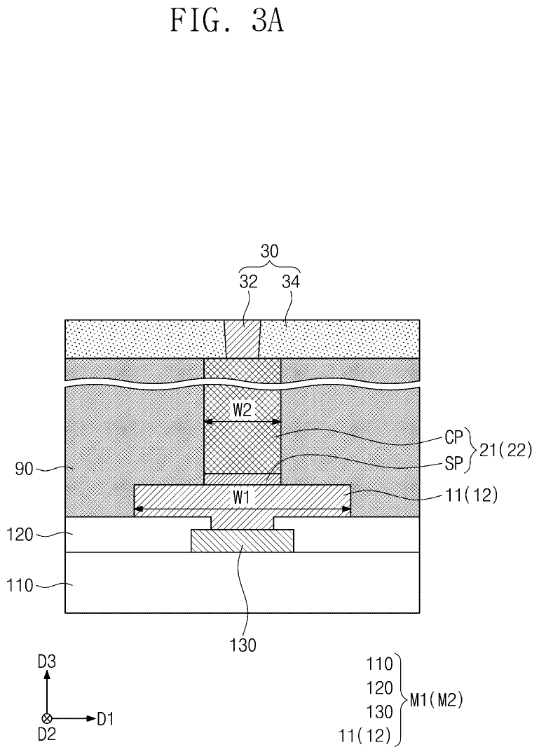

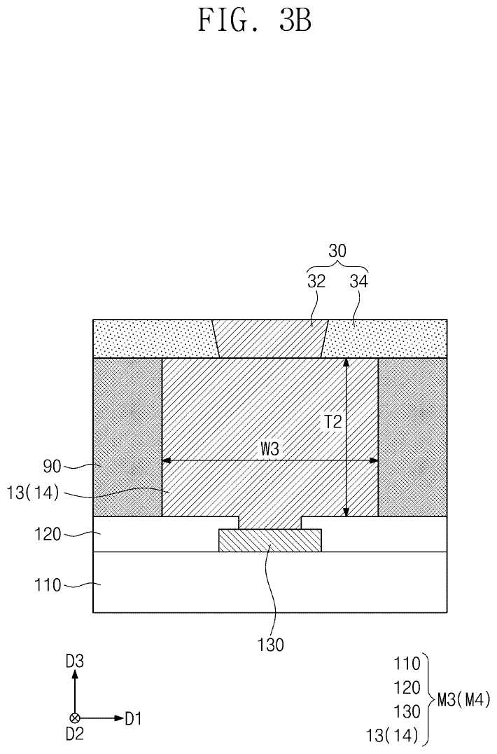

FIG. 3A is an enlarged view of the first chip pad of FIG. 2A and a periphery thereof, according to some embodiments of the present disclosure;

FIG. 3B is an enlarged view of the third chip pad of FIG. 2B and a periphery thereof, according to some embodiments of the present disclosure;

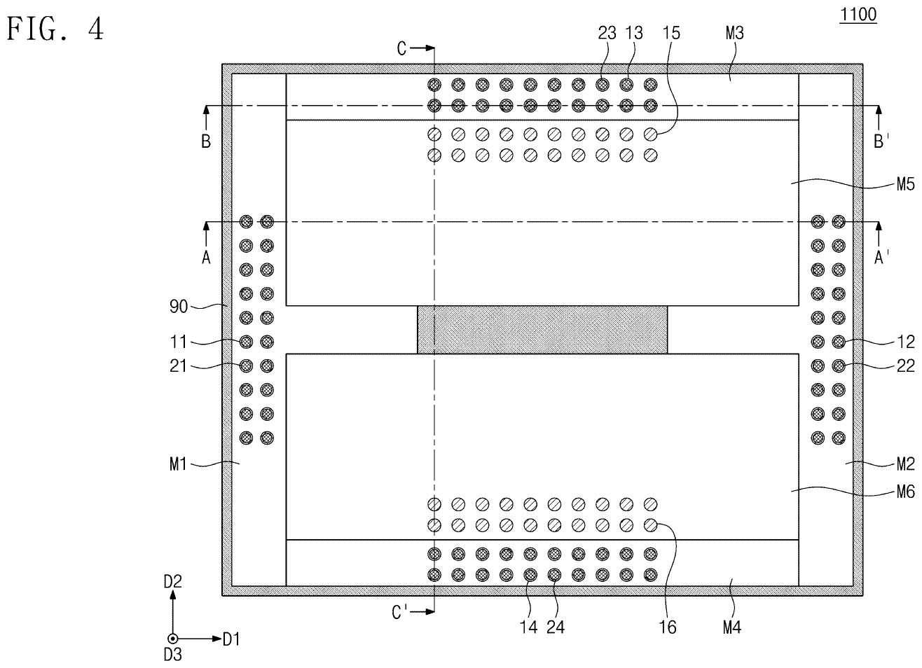

FIG. 4 is a plan view of a semiconductor package according to some embodiments;

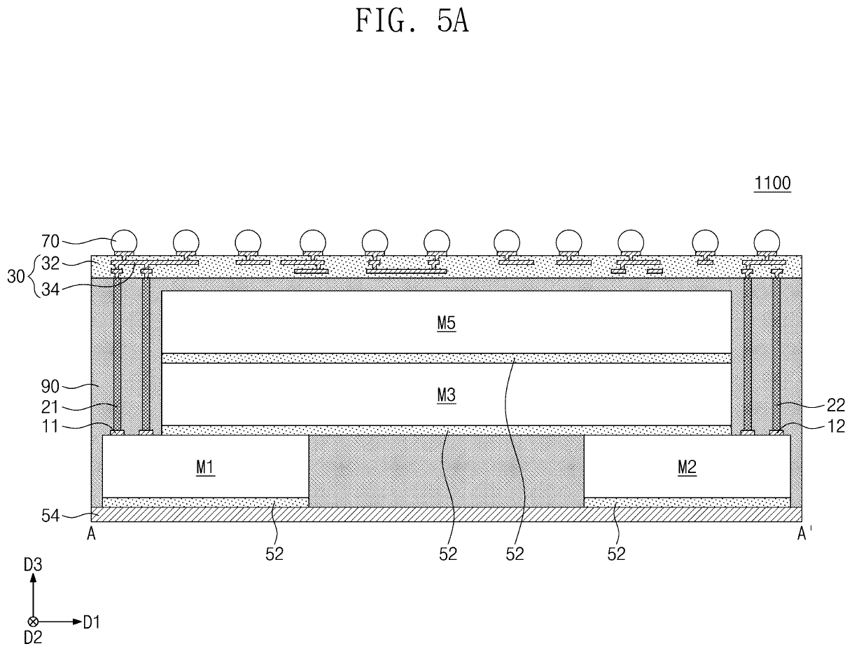

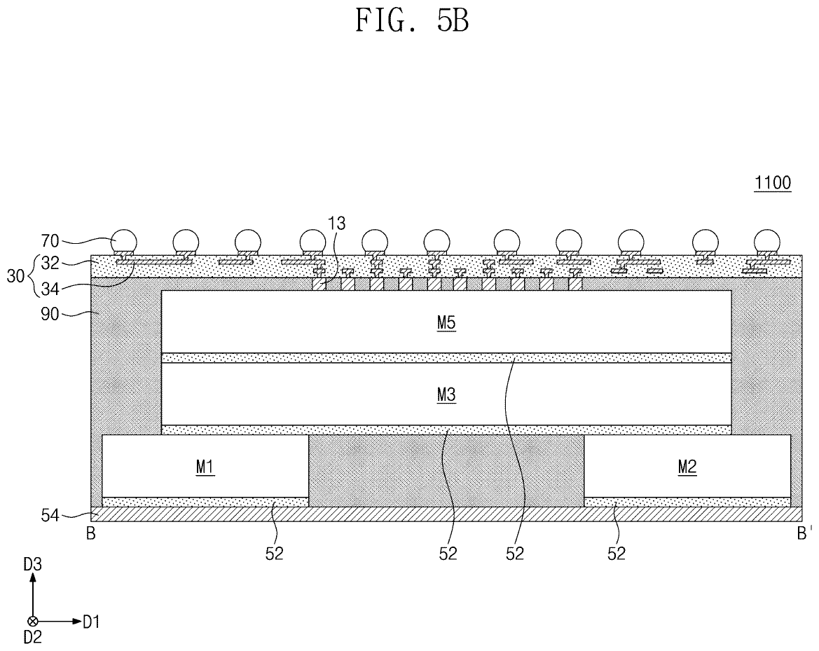

FIG. 5A is a cross-sectional view taken along line A-A′ of FIG. 4 according to some embodiments of the present disclosure;

FIG. 5B is a cross-sectional view taken along line B-B′ of FIG. 4 according to some embodiments of the present disclosure;

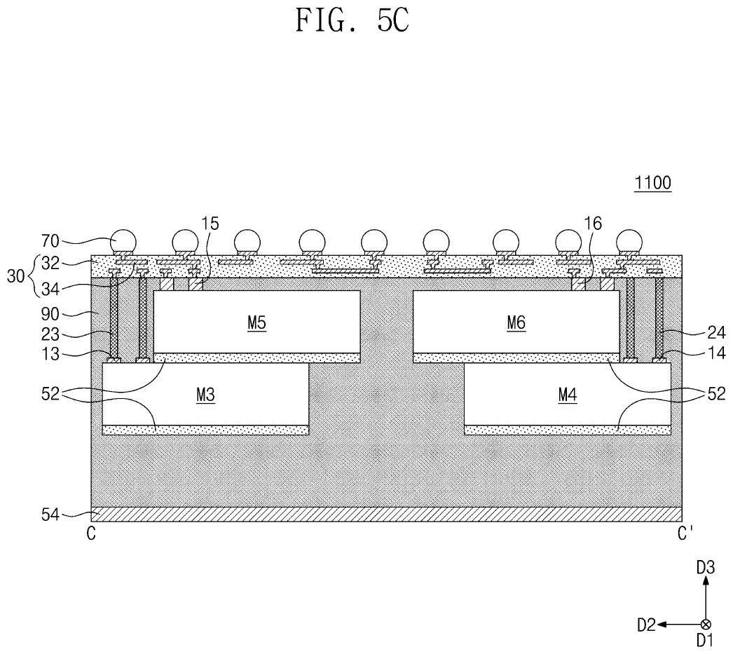

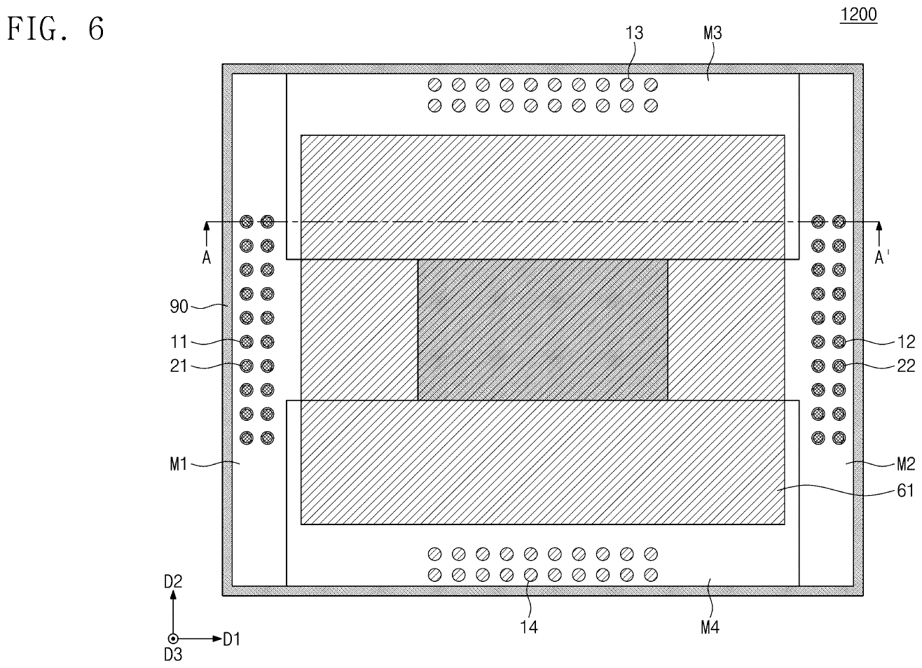

FIG. 6 is a plan view of a semiconductor package according to some embodiments;

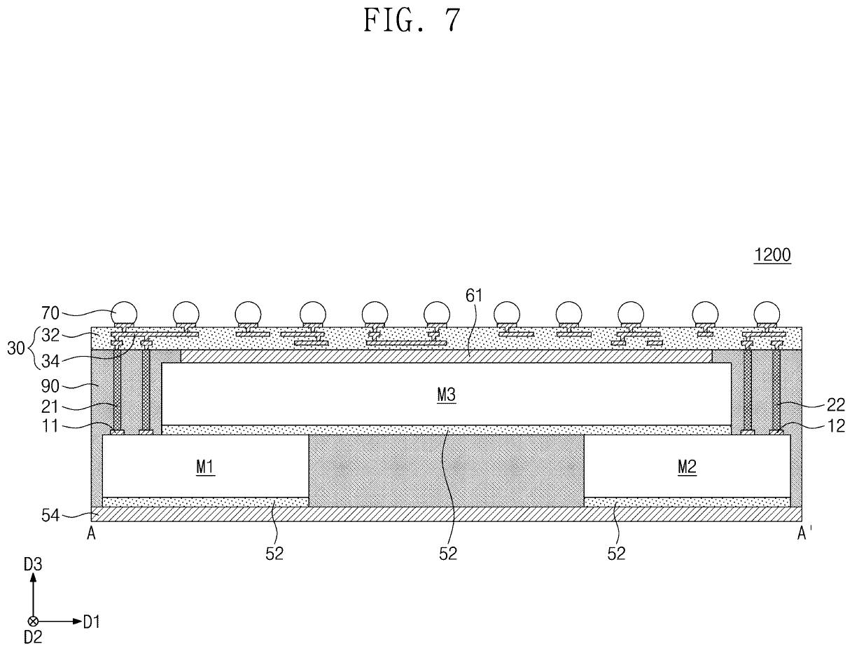

FIG. 7 is a cross-sectional view taken along line A-A′ of FIG. 6 according to some embodiments of the present disclosure;

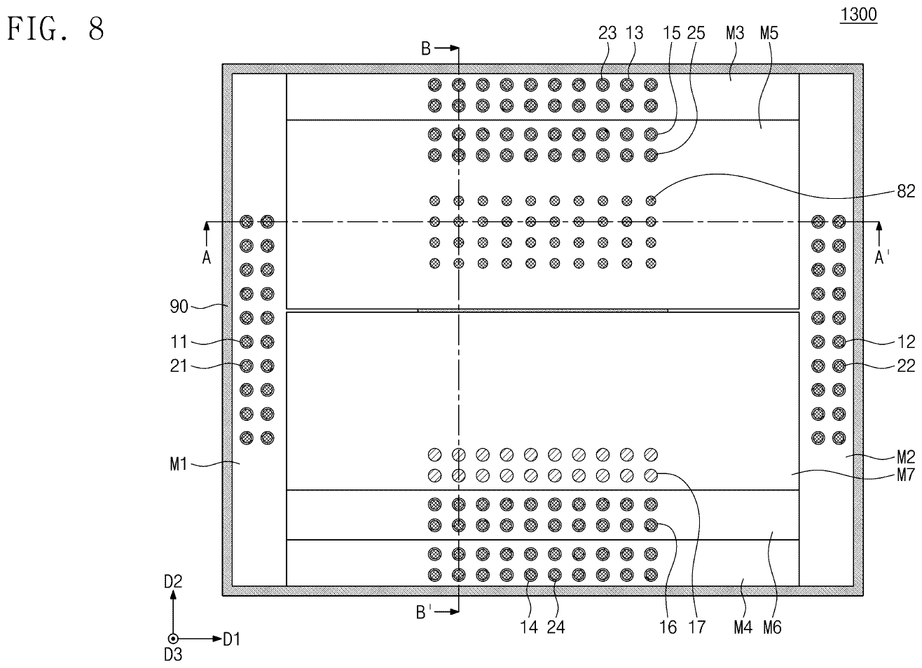

FIG. 8 is a plan view of a semiconductor package according to some embodiments;

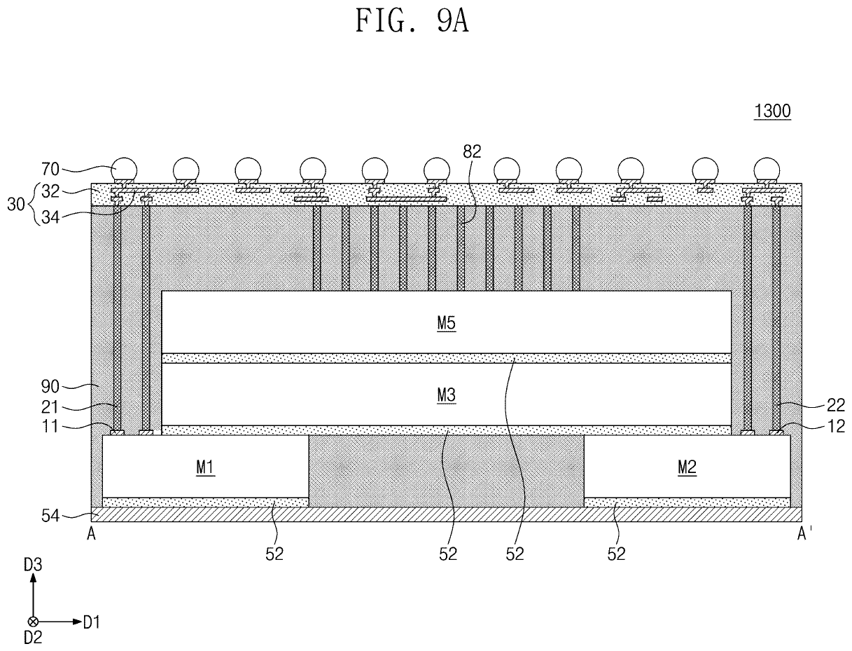

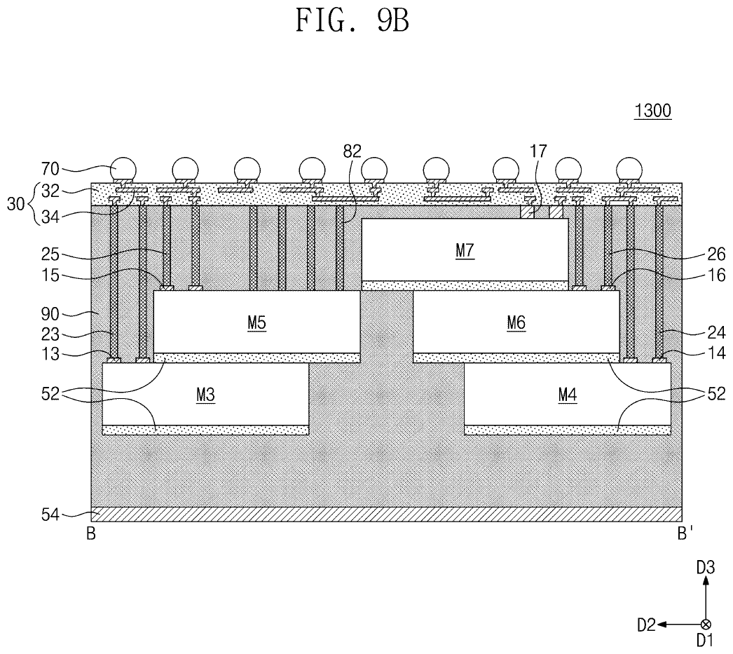

FIG. 9A is a cross-sectional view taken along line A-A′ of FIG. 8 according to some embodiments of the present disclosure;

FIG. 9B is a cross-sectional view taken along line B-B′ of FIG. 8 according to some embodiments of the present disclosure;

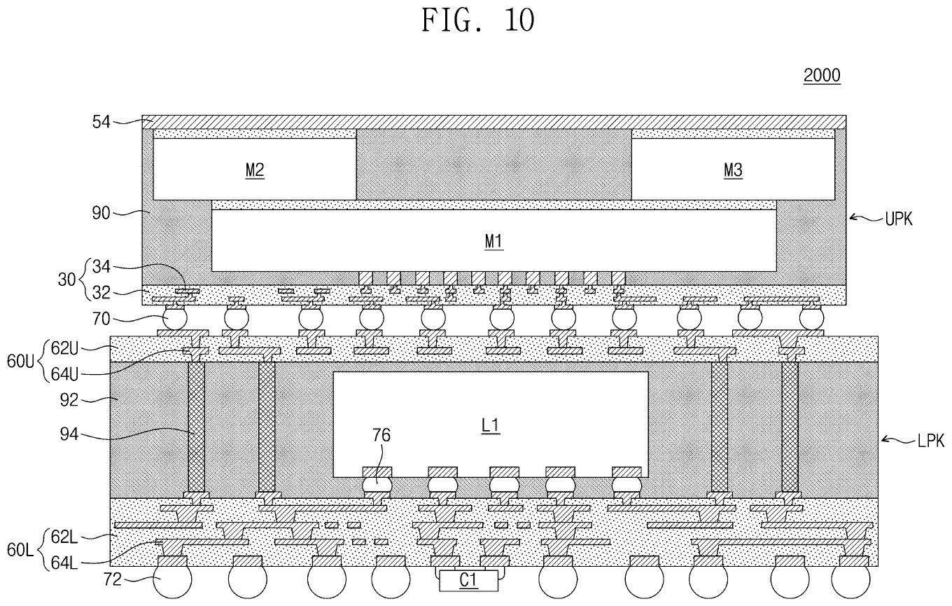

FIG. 10 is a cross-sectional view of a semiconductor package according to some embodiments;

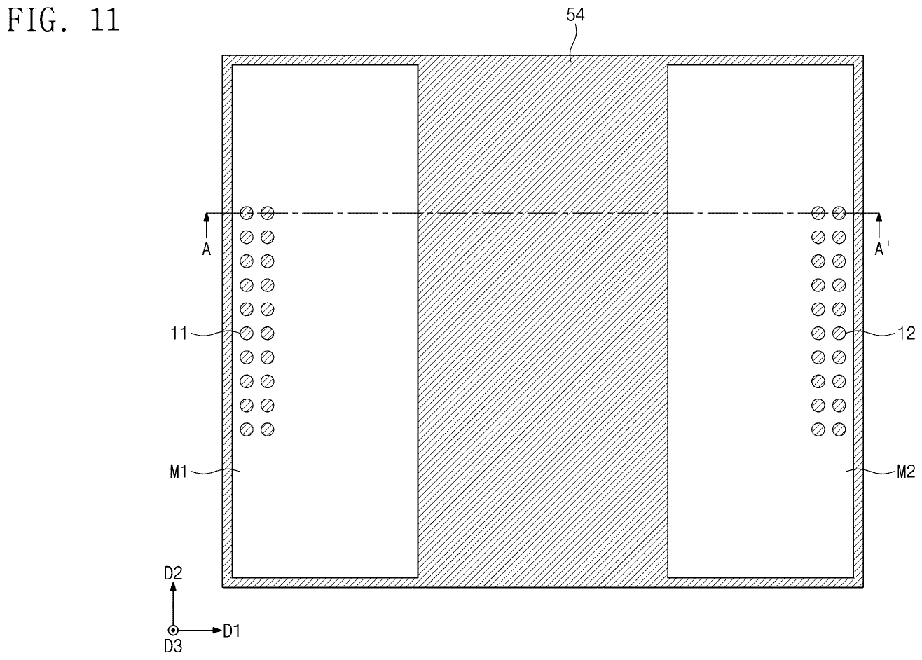

FIGS. 11, 13, 17, and 20 are plan views illustrating a manufacturing process of a semiconductor package according to some embodiments of the present disclosure;

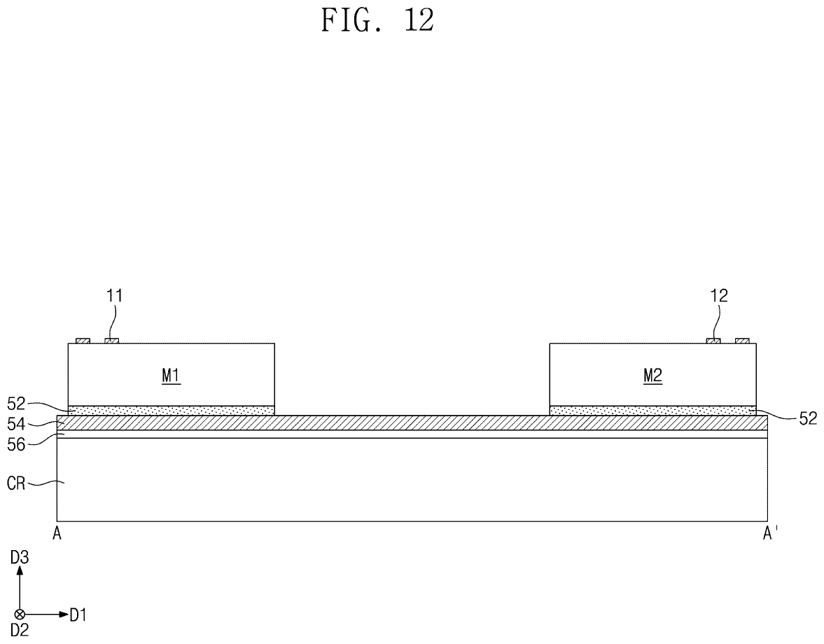

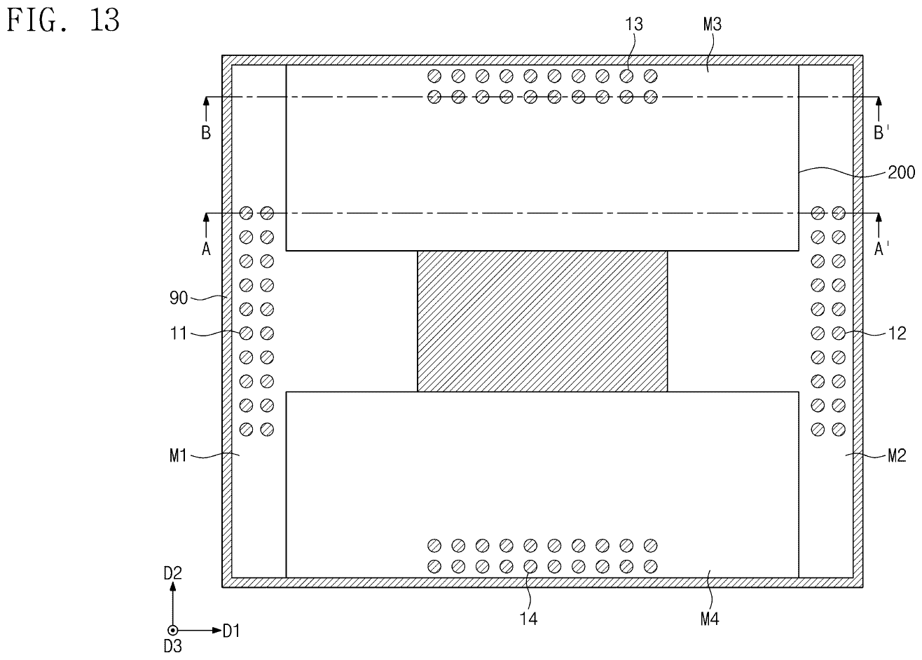

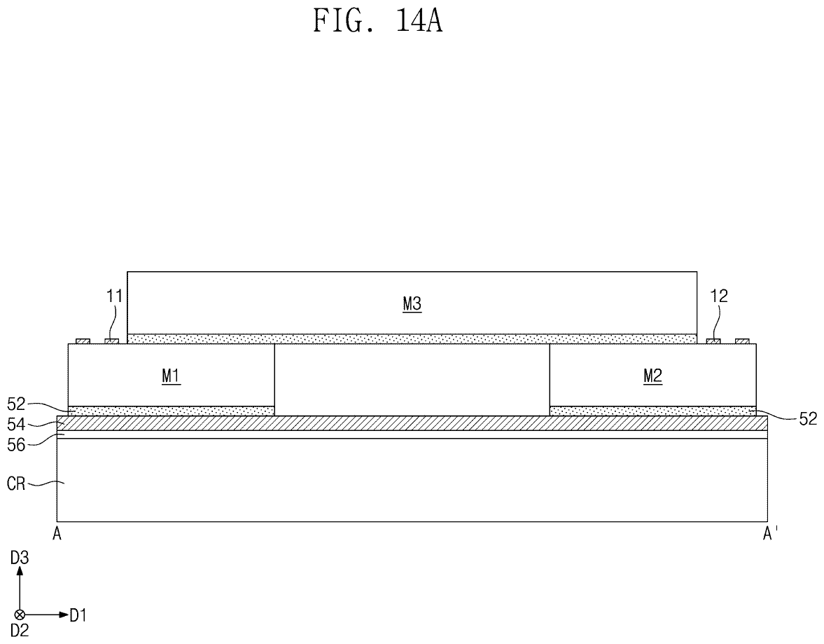

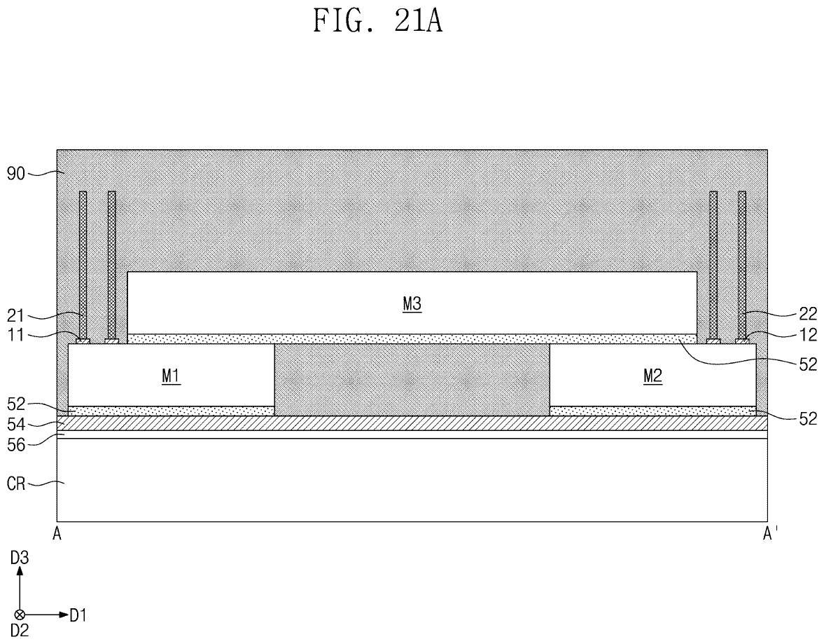

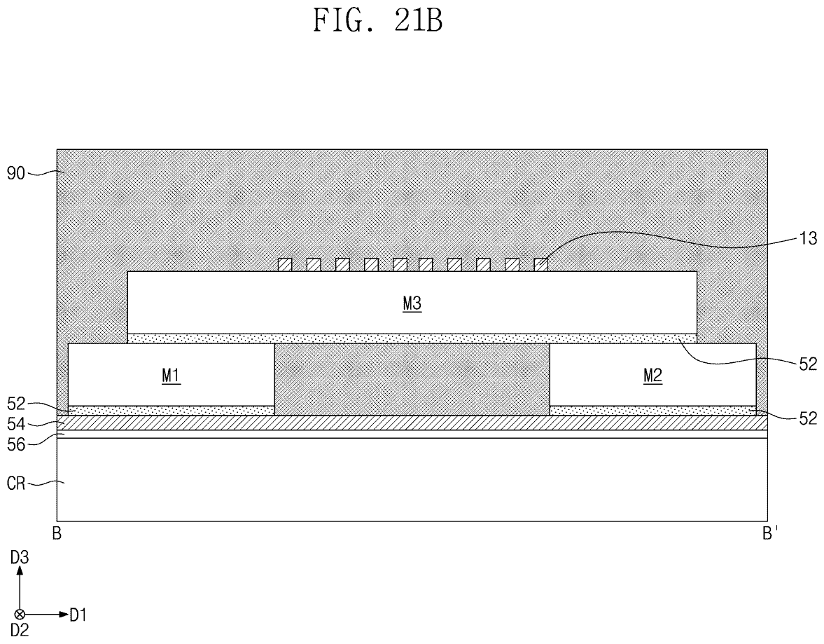

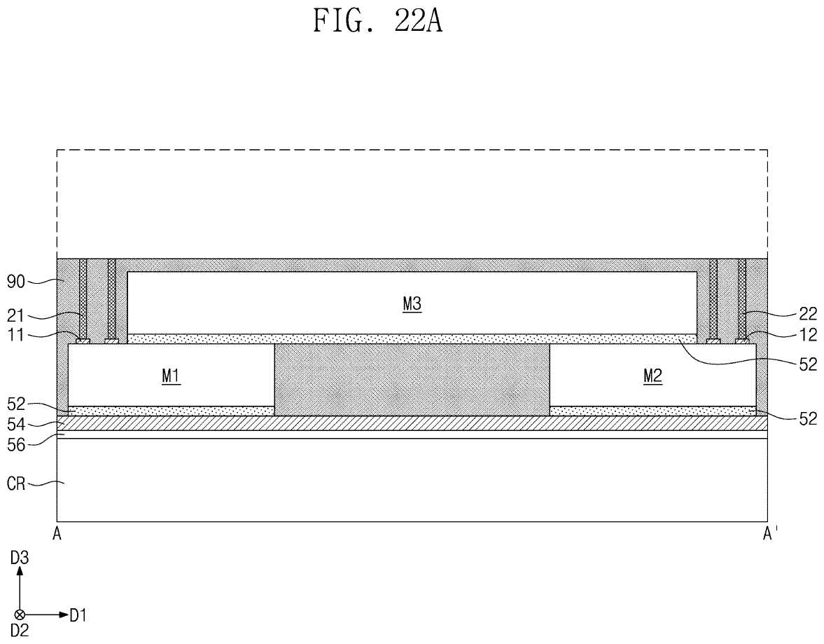

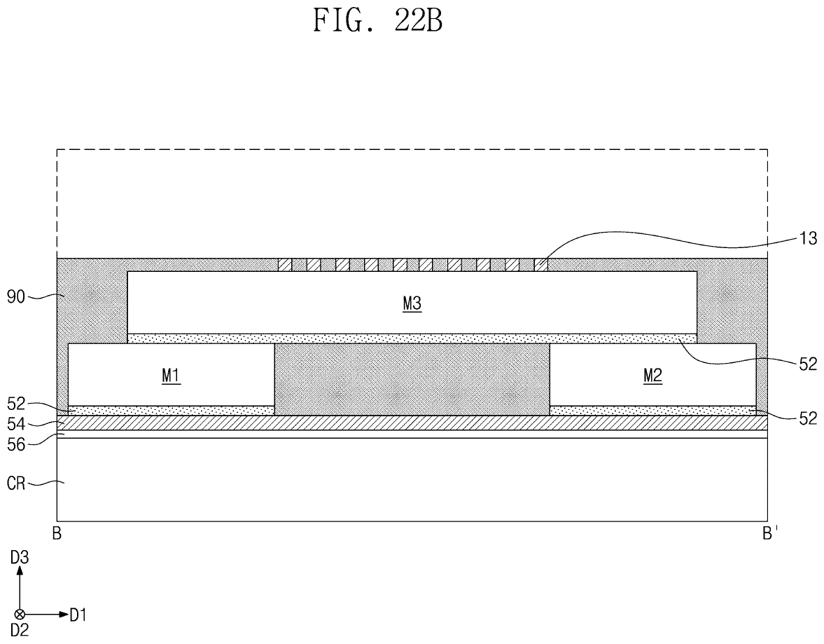

FIGS. 12, 14A, 14B, 15A, 15B, 18A, 18B, 21A, 21B, 22A, and 22B are cross-sectional views illustrating a manufacturing process of a semiconductor package according to some embodiments of the present disclosure;

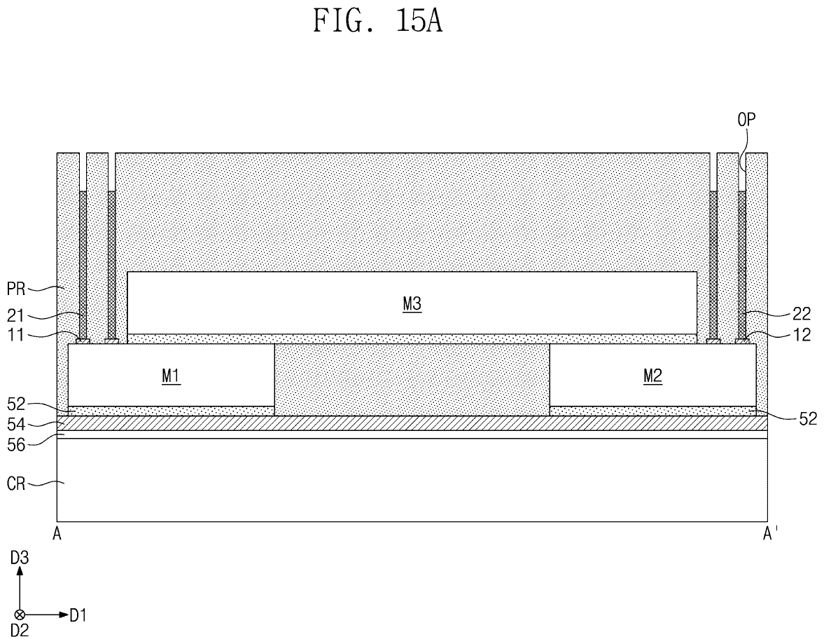

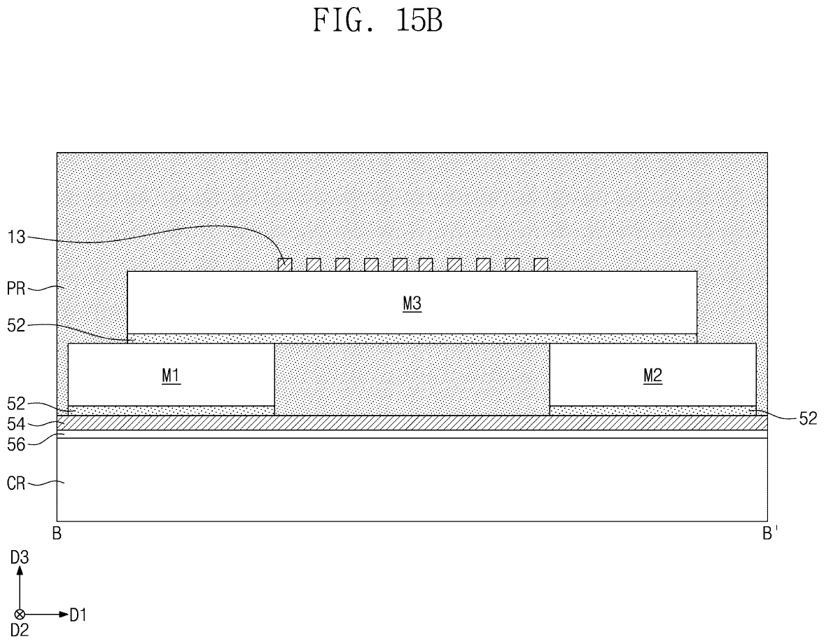

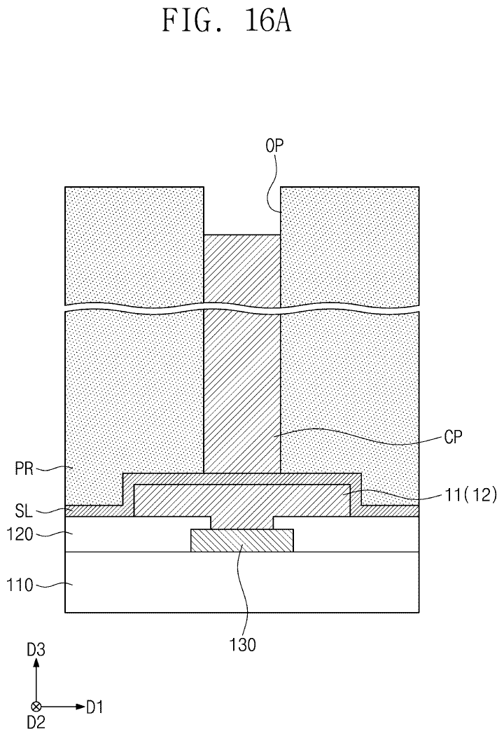

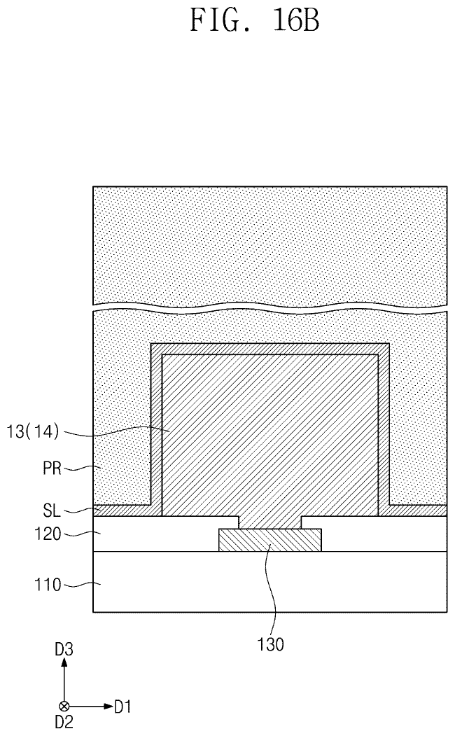

FIG. 16A is an enlarged view of the first chip pad of FIG. 15A and a periphery thereof, according to some embodiments of the present disclosure;

FIG. 16B is an enlarged view of the third chip pad of FIG. 15B and a periphery thereof, according to some embodiments of the present disclosure;

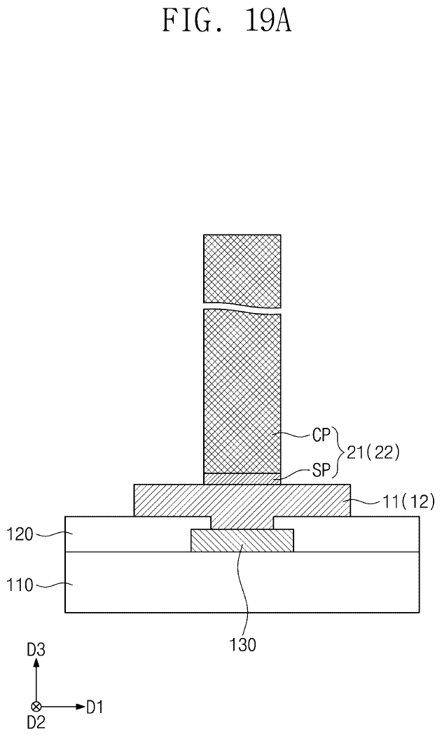

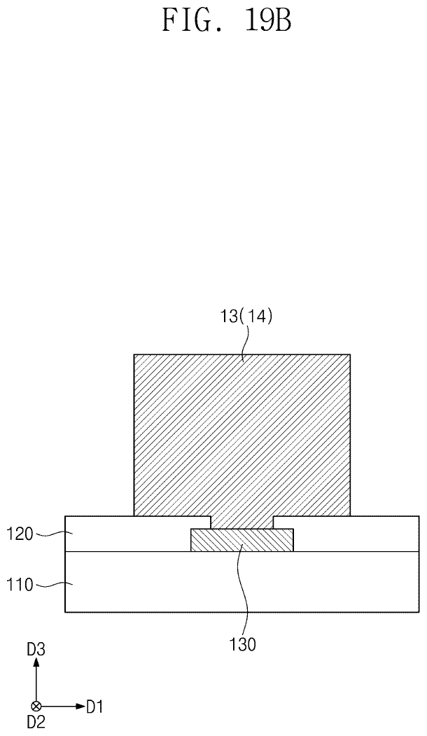

FIG. 19A is an enlarged view of the first chip pad of FIG. 18A and a periphery thereof, according to some embodiments of the present disclosure; and

FIG. 19B is an enlarged view of the third chip pad of FIG. 18B and a periphery thereof, according to some embodiments of the present disclosure.

### DETAILED DESCRIPTION

Hereinafter, a semiconductor package according to the embodiments of the present disclosure will be described with reference to the drawings.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

FIG. 1 is a plan view of a semiconductor package according to some embodiments of the present disclosure. FIG. 2A is a cross-sectional view taken along line A-A′ of FIG. 1. FIG. 2B is a cross-sectional view taken along line B-B′ of FIG. 1. FIG. 3A is an enlarged view of the first chip pad of FIG. 2A and a periphery thereof. FIG. 3B is an enlarged view of the third chip pad of FIG. 2B and a periphery thereof. Some elements, which are illustrated in other figures, are not illustrated in FIG. 1 to clearly show one or more embodiments of the present disclosure.

Referring to FIGS. 1, 2A, and 2B, a semiconductor package 1000 may include a first semiconductor chip M1, a second semiconductor chip M2, a third semiconductor chip M3, a fourth semiconductor chip M4, a first vertical conductive structure 21, a second vertical conductive structure 22, a first molding film 90, an adhesive layer 52, a redistribution layer 30, a connection terminal 70, and a support substrate 54.

The support substrate 54 may serve as a substrate on which the first semiconductor chip M1 and the second semiconductor chip M2 are arranged during a process of forming the semiconductor package 1000 that will be described later. The support substrate 54 may be any one of a semiconductor substrate (e.g., silicon substrate), a metal substrate, a polymer substrate, or any other suitable substrate material known to one of ordinary skill in the art. When the support substrate 54 is a metal substrate, the support substrate 54 may include a metal material such as aluminum, copper, aluminum/copper alloy, and stainless steel. The support substrate 54 may dissipate heat generated in the semiconductor package 1000 to the outside.

In one or more examples, the first semiconductor chip M1, the second semiconductor chip M2, the third semiconductor chip M3, and the fourth semiconductor chip M4 may be the same semiconductor chips. In one or more examples, semiconductor chips being the same semiconductor chips indicate that the semiconductor chips include the same integrated circuit. In one or more examples, being the same semiconductor chips may indicate that the semiconductor chips have substantially the same length, width, and height. Furthermore, being the same semiconductor chips indicates that the number and arrangement of chip pads, described below, in the semiconductor chips are substantially the same. The first to fourth semiconductor chips M1 to M4 may each be any one of dynamic random access memory (DRAM), static random access memory (SRAM), a NAND-FLASH, or any other suitable integrate circuit known to one of ordinary skill in the art. Appropriately, the first to fourth semiconductor chips M1 to M4 may be DRAMs having the same integrated circuit.

The first to fourth semiconductor chips M1 to M4 may include a first surface referred to as an active surface on which an integrated circuit and chip pads are arranged and a second surface opposite to the first surface (e.g., active surface) and attached to the adhesive layer 52. The active surface may be located closer to the redistribution layer 30 than the surface attached to the adhesive layer 52.

The first semiconductor chip M1 and the second semiconductor chip M2 may be arranged on the support substrate 54. The first semiconductor chip M1 and the second semiconductor chip M2 may be spaced apart from each other in a direction D1 parallel with an upper surface 54a of the support substrate 54. In the present disclosure, a second direction D2 represents one direction parallel with the upper surface 54a of the support substrate 54 and perpendicular to the first direction D1. A third direction D3 represents one direction perpendicular to the upper surface 54a of the support substrate 54. For example, the third direction D3 is perpendicular to the first direction D1 and the second direction D2.

The first semiconductor chip M1 and the second semiconductor chip M2 may be attached to the support substrate 54. The adhesive layer 52 may be interposed between each of the first semiconductor chip M1 and the second semiconductor chip M2 and the support substrate 54. The adhesive layer 52 may be, for example, a die-attach film (DAF). The adhesive layer 52 may include, for example, a polymer material such as adhesive epoxy resin, polyimide, and acrylate.

The first semiconductor chip M1 may include a plurality of first chip pads 11 on the active surface. The first chip pads 11 may be arranged on an edge portion of the active surface of the first semiconductor chip M1. For example, the first semiconductor chip M1 may have a shape of a rectangle in a plan view, wherein short sides of the rectangle may extend in the first direction D1. Long sides of the rectangle may extend in the second direction D2. The first chip pads 11 may be located closer to a long side that is close to a corner portion of the support substrate 54 among two long sides facing each other. As understood by one of ordinary skill in the art, the chip pads are not limited to a rectangle shape, and may be any suitable shape known to one of ordinary skill in the art.

The first chip pads 11 may be arranged in the first direction D1 and the second direction D2. The first chip pads 11 may have a larger number of rows along the second direction D2 than the number of columns along the first direction D1. However, in one or more examples, the first chip pads 11 may have a larger number of columns in the first direction D1 than the number of rows along the second direction D2.

The first semiconductor chip M1 and the second semiconductor chip M2 may be positioned on the support substrate 54 such that the first semiconductor chip M1 is rotated 180 degrees with respect to the second semiconductor chip M2 along the direction D1. That is, the second semiconductor chip M2 may have a mirror pair relationship with the first semiconductor chip M1. For example, the first semiconductor chip M1 and the second semiconductor chip M2 may be positioned on the support substrate such that a distance of the first semiconductor chip M1 along the first direction D1 to a center of the support substrate 54 is equal to a distance of the second semiconductor chip M2 along the first direction D1 to the center of the support substrate 54. The second semiconductor chip M2 may include second chip pads 12, and the size and arrangement of the second chip pads 12 may substantially the same as the size and arrangement of the first chip pads 11.

The first vertical conductive structures 21 may be arranged on the first chip pads 11 of the first semiconductor chip M1. The second vertical conductive structures 22 may be arranged on the second chip pads 12 of the second semiconductor chip M2. The first vertical conductive structures 21 and the second vertical conductive structures 22 may be spaced apart from each other in the first direction D1 with the third semiconductor chip M3 and the fourth semiconductor chip M4 therebetween. As illustrated in FIG. 2A, the first vertical conductive structures 21 and the second vertical conductive structures 22 extend in the direction D3.

The third semiconductor chip M3 and the fourth semiconductor chip M4 may be arranged on the first semiconductor chip M1 and the second semiconductor chip M2. The third semiconductor chip M3 and the fourth semiconductor chip M4 may be arranged spaced apart from each other in the second direction D2.

The adhesive layer 52 may be disposed on a surface opposite to the active surface of the third semiconductor chip M3 and a surface opposite to the active surface of the fourth semiconductor chip M4. The third semiconductor chip M3 and the fourth semiconductor chip M4 may be attached to the first semiconductor chip M1 and the second semiconductor chip M2 through the adhesive layer 52. In a plan view, two side portions of the third semiconductor chip M3 and two side portions of the fourth semiconductor chip M4 may overlap the first semiconductor chip M1 and the second semiconductor chip M2 in the third direction D3. The third semiconductor chip M3 may include third chip pads 13 arranged on the active surface. In one or more examples, the third semiconductor chip M3 may be positioned on the first semiconductor chip M1 and the second semiconductor chip M2 such that the third semiconductor chip M3 is rotated 90 degrees clockwise from the first semiconductor chip M1 along the direction D2. The fourth semiconductor chip M4 may include fourth chip pads 14 arranged on the active surface. In one or more examples, the fourth semiconductor chip M4 may be positioned on the first semiconductor chip M1 and the second semiconductor chip M2 such that the fourth semiconductor chip M4 is rotated 270 degrees clockwise from the first semiconductor chip M1 along the direction D2. In one or more example, the fourth semiconductor chip M4 may be positioned on the first semiconductor chip M1 and the second semiconductor chip M2 such that the fourth semiconductor chip M4 is rotated 90 degrees counterclockwise from the first semiconductor chip M1.

In one or more examples, a total number of the first chip pads 11, a total number of the second chip pads 12, a total number of the third chip pads 13, and a total number of the fourth chip pads 14 may be the same. The first chip pads 11 and the second chip pads 12 may be exposed from the third semiconductor chip M3 and the fourth semiconductor chip M4. For example, the first chip pads 11 may be positioned on the first semiconductor chip 11 such that the first chip pads 11 are not covered by the third semiconductor chip M3, and the second chip pads 12 may be positioned on the second semiconductor chip 12 such that the second chip pads 12 are not covered by the third semiconductor chip M3. The first chip pads 11 and the second chip pads 12 may be arranged in m columns in the first direction D1, and may be arranged in n rows in the second direction D2. The third chip pads 13 and the fourth chip pads 14 may be arranged in n columns in the first direction D1, and may be arranged in m rows in the second direction D2. In one or more examples, m and n may be at least 1 and may be different natural numbers.

The molding film 90 may cover the upper surface 54a of the support substrate 54, upper surfaces and side surfaces of the first to fourth semiconductor chips M1 to M4, a side surface of the adhesive layer 52, and side surfaces of the vertical conductive structures 21 and 22. The molding film 90 may include an insulative polymer such as an epoxy molding compound (EMC).

The redistribution layer 30 may be disposed on the molding film 90. The redistribution layer 30 may be spaced apart from the support substrate 54 in the third direction D3 with the first to fourth semiconductor chips M1 to M4 therebetween. The redistribution layer 30 may include a redistribution pattern 34 and an insulating layer 32. The redistribution pattern 34 may be interposed in the insulating layer 32. The insulating layer 32 may include a photoimageable dielectric (PID). The PID may include, for example, a polymer material such as benzocyclobutene (BCB). The redistribution pattern 34 exposed from the insulating layer 32 may function as a pad. The connection terminals 70 may be arranged on the exposed redistribution pattern 34. The redistribution pattern 34 may include a seed pattern and a conductive pattern on the seed pattern. The seed pattern may include, for example, titanium/copper (Ti/Cu). The conductive pattern CP may include, for example, copper.

The connection terminal 70 may be, for example, a bump or a solder ball. As least some of the connection terminals 70 may be arranged in a diagonal direction with respect to the semiconductor chips M1 to M4. That is, the semiconductor package 1000 may be fan-out package, for example.

Referring to FIGS. 3A and 3B, the first to fourth semiconductor chips M1 to M4 may include a semiconductor substrate 110, a connection pad 130, and a protective insulating layer 120. An integrated circuit such as a transistor may be disposed on the semiconductor substrate 110. The connection pad 130 may be disposed on the semiconductor substrate 110, and may be electrically connected to the integrated circuit through lines. The connection pad 130 may be a metal pad, for example, an aluminum pad. The first chip pad 11 may be disposed on the connection pad 130. The protective insulating layer 120 may cover a side surface and a portion of an upper surface of the connection pad 130. The protective insulating layer 120 may include an inorganic insulating material such as silicon nitride (SiN), silicon oxide (SiO_{X}), silicon oxynitride (SiON), and silicon carbon nitride (SiCN). The protective insulating layer 120 may include a plurality of insulating layers. The chip pads 11, 12, 13, and 14 may be arranged on an upper surface of the connection pad 130 exposed from the insulating layer 120. The chip pads 11, 12, 13, and 14 may include metal, for example, copper, aluminum, and gold.

As illustrated in FIG. 3A, the first vertical conductive structure 21 and the second vertical conductive structure 22 may each include the seed pattern SP and the conductive pattern CP on the seed pattern SP. The seed pattern SP may include, for example, titanium/copper (Ti/Cu). The conductive pattern CP may include, for example, copper. The first and second chip pads 11 and 12 may have a first diameter W1, and the first and second vertical conductive structures 21 and 22 may have a second diameter W2. The diameter W2 may be smaller than the first width W1. The molding film 90 may cover and be in contact with side surfaces of the first and second vertical conductive structures 21 and 22. The molding film 90 may be in contact with a side surface of the seed pattern SP and a side surface of the conductive pattern CP. In one or more examples, a seed pattern may be a thin layer of metal that is created to serve as a template for the fabrication of a semiconductor device. The seed pattern may be used to create a template for subsequent fabrication steps, such as etching or deposition. In one or more examples, the seed pattern may be created using a sputtering process, which involves bombarding a metal target with high-energy ions to eject metal ions that are then deposited onto the wafer surface

Referring to FIG. 3B, the third chip pad 13 and the fourth chip pad 14 may be arranged on the connection pad 130. The third chip pad 13 and the fourth chip pad 14 may have a third diameter W3. The third diameter W3 may be substantially the same as the above first diameter W1.

Referring to FIGS. 3A and 3B, the first chip pad 11 and the second chip pad 12 may have a first thickness T1, and the third chip pad 13 and the fourth chip pad 14 may have a second thickness T2. The second thickness T2 may be larger than the first thickness T1. The first chip pad 11 and the second chip pad 12 may each be a low-thickness pad, and the third chip pad 13 and the fourth chip pad 14 may each be a high-thickness pad. For example, the second thickness T2 may be at least about 20 um larger than the first thickness T1. For example, a difference between the second thickness T2 and the first thickness T1 may be about 20 μm to about 90 μm. An upper surface of the first vertical conductive structure 21, an upper surface of the second vertical conductive structure 22, an upper surface of the third chip pad 13, and an upper surface of the fourth chip pad 14 may be exposed from the molding film 90. The upper surface of the first vertical conductive structure 21, the upper surface of the second vertical conductive structure 22, the upper surface of the third chip pad 13, and the upper surface of the fourth chip pad 14 may be in contact with the redistribution layer 30. In one or more examples, the upper surface of the first vertical conductive structure 21, the upper surface of the second vertical conductive structure 22, the upper surface of the third chip pad 13, and the upper surface of the fourth chip pad 14 may be in contact with the redistribution pattern 34.

According to the embodiments of the present disclosure, a third semiconductor chip may be stacked on a first semiconductor chip and a second semiconductor chip spaced apart from each other in a first direction. In the case of stacking in a pyramid form as described above, a height of a stack structure may be reduced compared to the case in which the first to third semiconductor chips are sequentially offset stacked in a third direction. These features advantageously result in a first effect that the first and second semiconductor chips that are symmetrically arranged may stably support the third semiconductor chip. Furthermore, these features advantageously result in a second effect that formation of a vertical conductive structure on a second chip pad may be skipped and first and second vertical conductive structures may have the same height compared to the case in which the first to third semiconductor chips are sequentially offset stacked in the third direction. As a result, a process time may be reduced compared to the case in which vertical conductive structures having different heights are formed on the first semiconductor chip and the second semiconductor chip.

FIG. 4 is a plan view of a semiconductor package according to some embodiments. FIG. 5A is a cross-sectional view taken along line A-A′ of FIG. 4. FIG. 5B is a cross-sectional view taken along line B-B′ of FIG. 4. Descriptions overlapping with the above descriptions provided with reference to FIGS. 1, 2A, and 2B will not be provided.

Referring to FIGS. 4, 5A, and 5B, a semiconductor package 1100 according to some embodiments may further include a fifth semiconductor chip M5, a sixth semiconductor chip M6, a third vertical conductive structure 23, and a fourth vertical conductive structure 24. The fifth semiconductor chip M5 and the sixth semiconductor chip M6 may be the same as the above-mentioned first to fourth semiconductor chips M1 to M4. In one or more examples, the third vertical conductive structures 23 and the fourth vertical conductive structures 24 may extend in the D3 direction.

The fifth semiconductor chip M5 may be disposed on the third semiconductor chip M3. In a plan view, the fifth semiconductor chip M5 may be disposed offset from the third semiconductor chip M3 in the second direction D2. In one or more examples, the fifth semiconductor chip M5 may be positioned on the third semiconductor chip M3 such that the fifth semiconductor chip M5 is rotated 90 degrees clockwise from the first semiconductor chip M1. The adhesive layer 52 may be disposed on an opposite surface of the active surface of the fifth semiconductor chip M5. The fifth semiconductor chip M5 may be attached to the third semiconductor chip M3 through the adhesive layer 52.

The sixth semiconductor chip M6 may be disposed on the fourth semiconductor chip M4. In a plan view, the sixth semiconductor chip M6 may be disposed offset from the fourth semiconductor chip M4 in the second direction D2. In one or more examples, the sixth semiconductor chip M6 may be positioned on the fourth semiconductor chip M4 such that the sixth semiconductor chip M6 is rotated 270 degrees clockwise from the first semiconductor chip M1. The adhesive layer 52 may be disposed on an opposite surface of the active surface of the sixth semiconductor chip M6. The sixth semiconductor chip M6 may be attached to the fourth semiconductor chip M4 through the adhesive layer 52.

The third chip pad 13 of the third semiconductor chip M3 and the fourth chip pad 14 of the fourth semiconductor chip M4 may each be a low-thickness pad. The third vertical conductive structure 23 may be disposed on the third chip pad 13. The fourth vertical conductive structure 24 may be disposed on the fourth chip pad 14. The third vertical conductive structure 23 and the fourth vertical conductive structure 24 may each include the seed pattern SP and the conductive pattern CP like the above-mentioned first vertical conductive structure 21. A height of the third vertical conductive structure 23 and a height of the fourth vertical conductive structure 24 may be lower than a height of the first vertical conductive structure 21 and a height of the second vertical conductive structure 22. The fifth semiconductor chip M5 may include fifth chip pads 15, and the sixth semiconductor chip M6 may include sixth chip pads 16. The fifth chip pads 15 of the fifth semiconductor chip M5 and the sixth chip pads 16 of the sixth semiconductor chip M6 may each be a high-thickness pad.

FIG. 6 is a plan view of a semiconductor package according to some embodiments. FIG. 7 is a cross-sectional view taken along line A-A′ of FIG. 6. Descriptions overlapping with the above descriptions provided with reference to FIGS. 1, 2A, and 2B will not be provided.

Referring to FIGS. 6 and 7, a semiconductor package 1200 may further include a dummy plate 61. The dummy plate 61 may be disposed on the third semiconductor chip M3 and the fourth semiconductor chip M4. The dummy plate 61 may include, for example, metal such as copper. A thickness of the dummy plate 61 may be substantially the same as the thickness T2 of the third chip pad 13 and/or the thickness T2 of the fourth chip pad 14 of FIG. 3B. The dummy plate 61 may be disposed on a center portion of the semiconductor package 1200 so as to be in balance with the vertical conductive structures 21 and 22 that are mostly arranged on an outer peripheral portion. As a result, mechanical stress and warpage may be reduced.

FIG. 8 is a plan view of a semiconductor package according to some embodiments. FIG. 9A is a cross-sectional view taken along line A-A′ of FIG. 8. FIG. 9B is a cross-sectional view taken along line B-B′ of FIG. 8. Differences from the semiconductor package 1100 described with reference to FIGS. 4, 5A, and 5B will be described, and common descriptions will not be provided.

Referring to FIGS. 8, 9A, and 9B, a semiconductor package 1300 may further include a seventh semiconductor chip M7 and a dummy vertical structure 82. The seventh semiconductor chip M7 may be the same as the above-mentioned first to sixth semiconductor chips M1 to M6. The seventh semiconductor chip M7, for example, may be disposed on the sixth semiconductor chip M6. In a plan view, the seventh semiconductor chip M7 may be stacked offset from the sixth semiconductor chip M6 in the second direction D2. As a result, in a plan view, the fourth chip pads 14, the sixth chip pads 16, and the seventh chip pads 17 may be arranged spaced apart in the second direction D2.

The third chip pad 13, the fourth chip pad 14, the fifth chip pad 15, and the sixth chip pad 16 may each be a low-thickness pad. The third vertical conductive structure 23, the fourth vertical conductive structure 24, a fifth vertical conductive structure 25, and a sixth vertical conductive structure 26 may be arranged on the third chip pad 13, the fourth chip pad 14, the fifth chip pad 15, and the sixth chip pad 16.

The dummy vertical structures 82 may be arranged on the fifth semiconductor chip M5. The dummy vertical structure 82 may include the seed pattern SP and the conductive pattern CP like the first vertical conductive structure 21. The dummy vertical structure 82 may include metal and may be formed together with the vertical conductive structures 21, 22, 23, 24, 25, and 26. The dummy vertical structure 82 may be in contact with the fifth semiconductor chip M5 but may not be electrically connected to the integrated circuit of the fifth semiconductor chip M5. The dummy vertical structure 82 may be in contact with the insulating layer 32 or the redistribution pattern 34 of the redistribution layer 30. The dummy vertical structure 82 may be disposed on a center portion of the semiconductor package 1300 so as to be in balance with the vertical conductive structures 21, 22, 23, 24, 25, and 26 that are mostly arranged on an outer peripheral portion. As a result, mechanical stress and warpage may be reduced.

FIG. 10 is a cross-sectional view of a semiconductor package according to some embodiments. Referring to FIG. 10, a semiconductor package 2000 according to the present example may be an example of a package-on-package structure. The semiconductor package 2000 may include a lower semiconductor package LPK and an upper semiconductor package UPK on the lower semiconductor package LPK. The upper semiconductor package UPK may be substantially the same as the semiconductor package 1000 described above with reference to FIGS. 1, 2A, and 2B.

The lower semiconductor package LPK may include a lower redistribution layer 60L, a lower semiconductor chip L1, an upper redistribution layer 60U, a conductive pillar 94, and a lower molding film 92. The above molding film 90 is referred to as an upper molding film 91. In the package-on-package structure, the semiconductor chips M1, M2, M3, and M4 of the upper semiconductor package UPK may be referred to as an upper semiconductor chip. For example, the lower semiconductor chip L1 may be a logic chip, and the upper semiconductor chips M1, M2, M3, and M4 may be a memory chip. The lower semiconductor chip L1 and the upper semiconductor chips M1, M2, M3, and M4 may include heterogeneous semiconductor chips. The lower semiconductor package LPK may have a chip-last or redistribution (RDL)-first fan-out wafer-level package structure. According to some embodiments, the lower semiconductor package LPK may have a chip-first or RDL-last fan-out wafer-level package structure unlike the illustrated structure.

The lower semiconductor chip L1 may be disposed on the lower redistribution layer 60L. The lower semiconductor chip L1 may be electrically connected to the lower redistribution layer 60L through an internal connection terminal 76.

The lower redistribution layer 60L may include a lower insulating layer 62L and a lower redistribution pattern 64L. The upper redistribution layer 60U may include an upper insulating layer 62U and an upper redistribution pattern 64U. The lower insulating layer 62L and the upper insulating layer 62U may include the same photoimageable dielectric as the above-mentioned insulating layer 32. The lower redistribution pattern 64L and the upper redistribution pattern 64U may include the same metal material as the above-mentioned redistribution pattern 34. The conductive pillar 94 may be spaced apart from the lower semiconductor chip L1 in the first direction and/or the second direction D2, and may electrically connect the lower redistribution layer 60L and the upper redistribution layer 60U.

An external connection terminal 72 may be connected to one surface of the lower redistribution layer 60L. The internal connection terminal 76 and the external connection terminal 72 may include solder, for example. An upper surface of the lower redistribution layer 60L and the lower semiconductor chip L1 may be covered with the lower molding film 92. The lower molding film 92 may include an insulative polymer such as an EMC. The upper redistribution layer 60L may be disposed on the lower molding film 92.

According to some embodiments, a passive element C1 such as a capacitor disposed on a lower surface of the lower redistribution layer 60L may be further included.

FIGS. 11, 13, 17, and 20 are plan views illustrating a manufacturing process of a semiconductor package according to some embodiments of the present disclosure. FIGS. 12, 14A, 14B, 15A, 15B, 18A, 18B, 21A, 21B, 22A, and 22B are cross-sectional views illustrating a manufacturing process of a semiconductor package according to some embodiments. FIG. 16A is an enlarged view of the first chip pad of FIG. 15A and a periphery thereof. FIG. 16B is an enlarged view of the third chip pad of FIG. 15B and a periphery thereof. FIG. 19A is an enlarged view of the first chip pad of FIG. 18A and a periphery thereof. FIG. 19B is an enlarged view of the third chip pad of FIG. 18B and a periphery thereof.

Referring to FIGS. 11 and 12, a carrier substrate CR and a temporary adhesive layer 56 on the carrier substrate CR may be prepared. The support substrate 54 may be disposed on the temporary adhesive layer 56. The first semiconductor chip M1 and the second semiconductor chip M2 may be prepared. Preparing the first semiconductor chip M1 and the second semiconductor chip M2 may include forming the first semiconductor chip M1 and the second semiconductor chip M2 by forming chip regions having the same integrated circuits on a first semiconductor wafer and then sawing the chip regions. Forming the first semiconductor chip M1 and the second semiconductor chip M2 may include adjusting the first chip pad 11 and the second chip pad 12 to have a low-thickness. Thereafter, the first semiconductor chip M1 and the second semiconductor chip M2 may be attached onto the support substrate 54 using the adhesive layer 52.

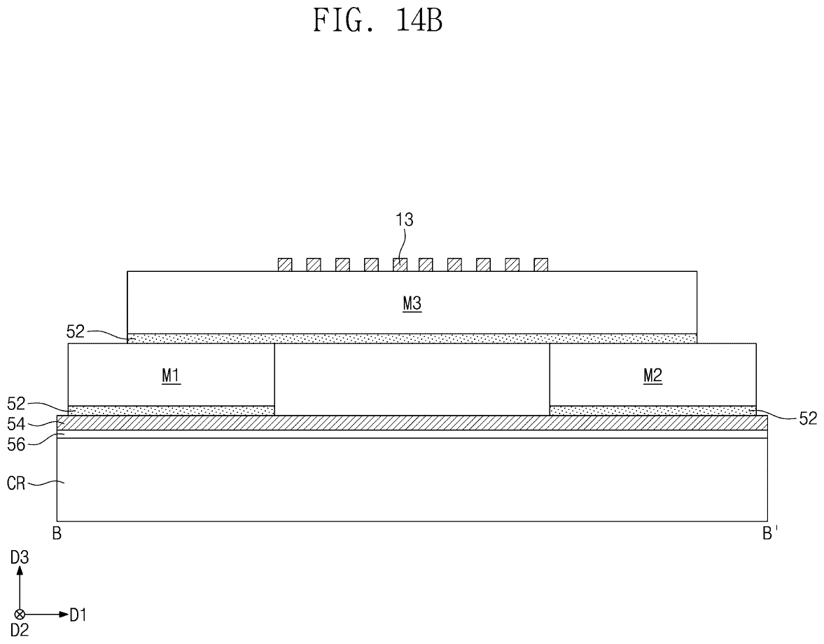

Referring to FIGS. 13, 14A, and 14B, the third semiconductor chip M3 and the fourth semiconductor chip M4 may be prepared. Preparing the third semiconductor chip M3 and the fourth semiconductor chip M4 may include forming the third semiconductor chip M3 and the fourth semiconductor chip M4 by forming chip regions having the same integrated circuits on a second semiconductor wafer and then sawing the chip regions. The integrated circuits formed on the first wafer and the integrated circuits formed on the second wafer may be the same. Forming the third semiconductor chip M3 and the fourth semiconductor chip M4 may include adjusting the third chip pad 13 and the fourth chip pad 14 to have a low-thickness. Thereafter, the third semiconductor chip M3 and the fourth semiconductor chip M4 may be attached onto the first semiconductor chip M1 and the second semiconductor chip M2 using the adhesive layer 52.

Referring to FIGS. 15A, 15B, 16A, and 16B, a seed layer SL may be formed on upper surfaces of the first to fourth semiconductor chips M1 to M4. The seed layer SL may include titanium/copper. Forming the seed layer SL may include forming the seed layer SL using any one method among physical vapor deposition (PVD), chemical vapor deposition (CVD), and sputtering.

After the seed layer SL is formed, a photoresist pattern PR including an opening OP that defines a space in which to form the first vertical conductive structures 21 and the second vertical conductive structures 22 may be formed. Forming the photoresist pattern PR may include forming a photoresist layer by applying a photoresist material and patterning the photoresist layer. The opening OP may expose the first chip pads 11 and the second chip pads 12. The third chip pads 13 and the fourth chip pads 14 may be covered with the photoresist pattern PR. The conductive patterns CP may be formed on the seed layer SL exposed from the photoresist pattern PR. Forming the conductive patterns CP may include the conductive patterns CP using an electroplating method in which the seed layer SL is used as an electrode.

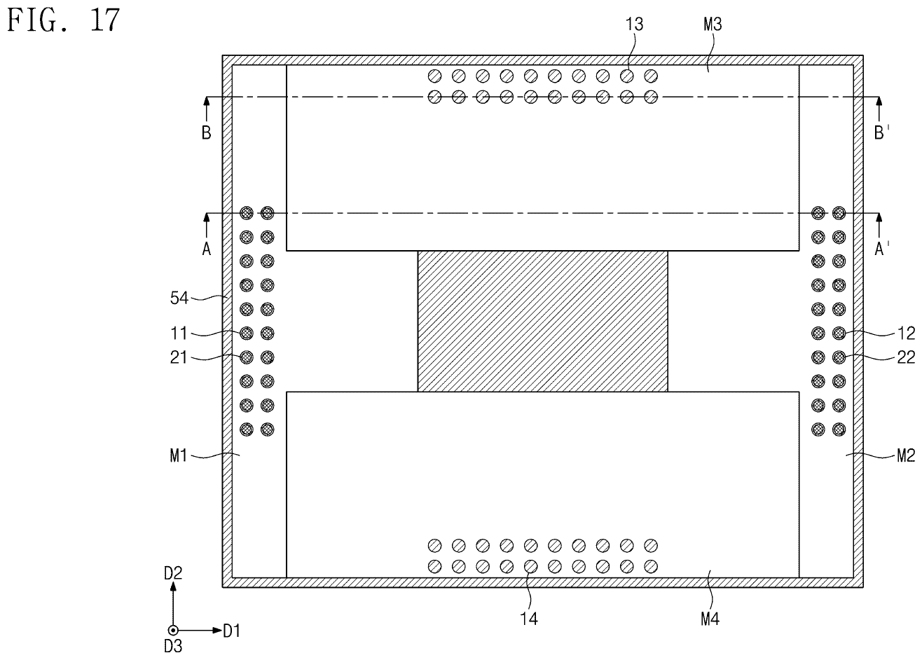

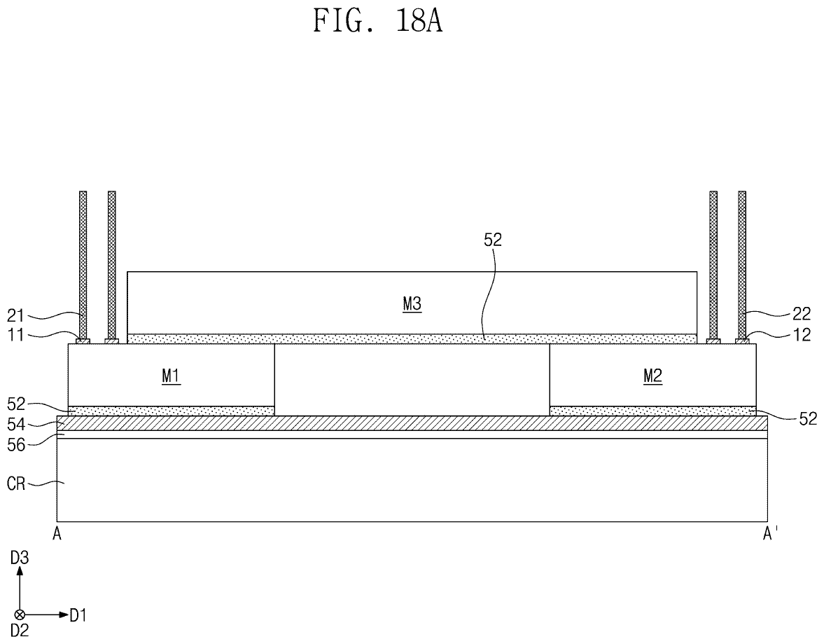

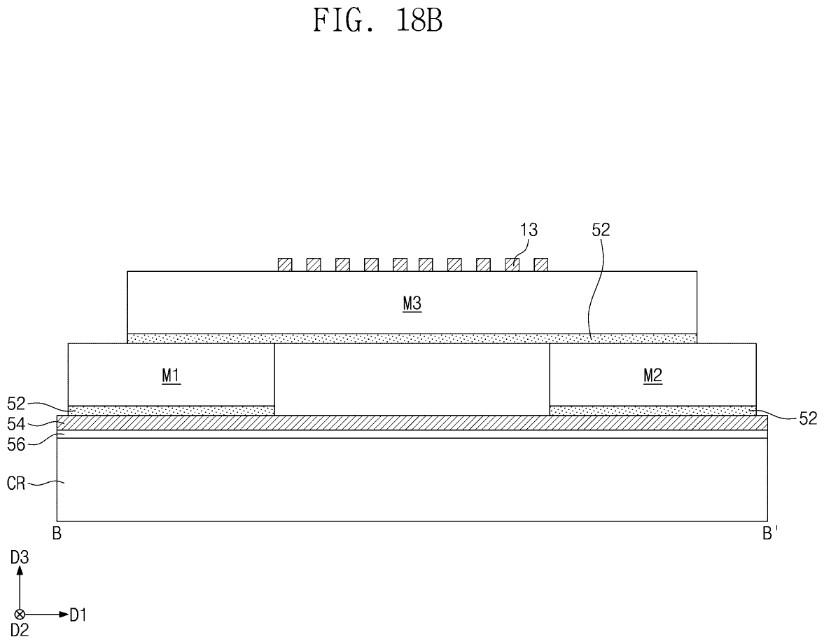

Referring to FIGS. 17, 18A, 18B, 19A, and 19B, the photoresist pattern PR may be removed. A portion of the exposed seed layer SL, which is not located under the conductive patterns CP, may be removed. A process of removing the portion of the seed layer SL may include an etching process. A remaining portion of the seed layer SL, which is located under the conductive pattern CP, may become the seed pattern SP.

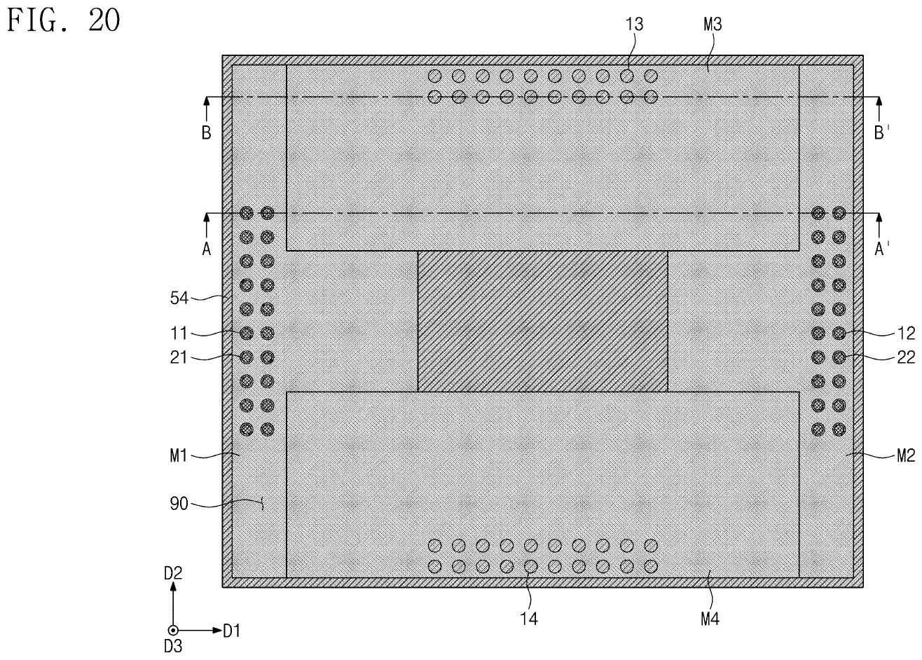

Referring to FIGS. 20, 21A, 21B, 22A, and 22B, the molding film 90 covering the first to fourth semiconductor chips M1 to M4 may be formed. Forming the molding film 90 may include applying a liquid or fluidic EMC and curing the same. Thereafter, the molding film 90 may be planarized. Planarizing the molding film 90 may include reducing a height of the molding film 90. The upper surface of the first vertical conductive structure 21, the upper surface of the second vertical conductive structure 22, the upper surface of the third chip pad 13, and the upper surface of the fourth chip pad 14 may be exposed by planarizing the molding film 90. As a result of the planarizing, the upper surface of the first vertical conductive structure 21, the upper surface of the second vertical conductive structure 22, the upper surface of the third chip pad 13, and the upper surface of the fourth chip pad 14 may be aligned at substantially the same height.

Referring back to FIGS. 1, 2A, and 2B, the redistribution layer 30 may be formed on an upper surface of the molding film 90, the upper surface of the first vertical conductive structure 21, the upper surface of the second vertical conductive structure 22, the upper surface of the third chip pad 13, and the upper surface of the fourth chip pad 14. The connection terminal 70 may be formed after the redistribution layer 30 is formed. Thereafter, the carrier substrate CR and the temporary adhesive layer 56 may be removed.

A semiconductor package according to one or more embodiments of the present disclosure may include the same semiconductor chips stacked in a pyramid form and vertical conductive structures respectively arranged on the semiconductor chips and having the same height. Due to the above structure, the semiconductor package is stable from a structural aspect, and a process time may be reduced. As a result, the reliability of the structure of the semiconductor package and a method for manufacturing the same may be improved.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A semiconductor package comprising:
a support substrate;
a first semiconductor chip on the support substrate, the first semiconductor chip comprising one or more first chip pads;
a second semiconductor chip spaced apart from the first semiconductor chip in a first direction parallel with a surface of the support substrate, the second semiconductor chip comprising one or more second chip pads;
a third semiconductor chip on the first semiconductor chip and the second semiconductor chip, the third semiconductor chip comprising one or more third chip pads;
one or more first conductive structures on the one or more first chip pads, the one or more first conductive structures extending in a second direction perpendicular to the first direction;
one or more second conductive structures on the one or more second chip pads, the one or more second conductive structures extending in the second direction; and
a redistribution layer on the one or more first conductive structures, the one or more second conductive structures, and the one or more third chip pads,
wherein the one or more first conductive structures and the one or more second conductive structures are spaced apart from each other in the first direction with the third semiconductor chip therebetween, and
a number of the one or more first chip pads, a number of the one or more second chip pads, and a number of the one or more third chip pads are the same.

2. The semiconductor package of claim 1, wherein the first semiconductor chip, the second semiconductor chip, and the third semiconductor chip have a same size in a plan view.

3. The semiconductor package of claim 1, wherein the one or more first chip pads and the one or more second chip pads are not covered by the third semiconductor chip.

4. The semiconductor package of claim 1,
wherein the one or more first chip pads and the one or more second chip pads are arranged in m columns in the first direction,
wherein the one or more first chip pads and the one or more second chip pads are arranged in n rows in a third direction that is parallel with the surface of the support substrate and perpendicular to the first direction,
wherein the one or more third chip pads are arranged in n columns in the first direction and m rows in the third direction, and
wherein m and n are at least 1 and are different natural numbers.

5. The semiconductor package of claim 1, further comprising:
a molding film between the redistribution layer and the support substrate,
wherein each of the one or more first conductive structures and each of the one or more second conductive structures comprise:
a seed pattern; and
a conductive pattern on the seed pattern, and
wherein the molding film is in direct contact with the conductive pattern.

6. The semiconductor package of claim 1, wherein the first semiconductor chip, the second semiconductor chip, and the third semiconductor chip include a same integrated circuit.

7. The semiconductor package of claim 1,
wherein each of the one or more first chip pads have a first thickness,
wherein each of the one or more second chip pads have a second thickness,
wherein each of the one or more third chip pads have a third thickness, and
wherein the third thickness is larger than the first thickness and the second thickness.

8. The semiconductor package of claim 1, further comprising:
a fourth semiconductor chip on the third semiconductor chip,
wherein, in a plan view, the fourth semiconductor chip is offset from the third semiconductor chip in a third direction that is parallel with the surface of the support substrate and perpendicular to the first direction.

9. The semiconductor package of claim 8, further comprising:
one or more third conductive structures on the one or more third chip pads, the one or more third conductive structures extending in the second direction
wherein a height of the one or more third conductive structures is lower than a height of the one or more first conductive structures.

10. The semiconductor package of claim 1, further comprising:
a dummy plate on the third semiconductor chip,
wherein the dummy plate is spaced apart from the one or more first conductive structures and the one or more second conductive structures in the first direction, and spaced apart from the one or more third chip pads in a third direction that is parallel with the surface of the support substrate and perpendicular to the first direction.

11. The semiconductor package of claim 1, further comprising;
a fourth semiconductor chip on the first semiconductor chip and the second semiconductor chip;
a fifth semiconductor chip on the fourth semiconductor chip;
one or more third conductive structures on the one or more third chip pads, the one or more third conductive structures extending in the second direction; and
one or more dummy structures on the third semiconductor chip, the one or more dummy structures extending in the second direction,
wherein the fourth semiconductor chip is spaced apart from the third semiconductor chip in a third direction that is parallel with the surface of the support substrate and perpendicular to the first direction,
wherein the fifth semiconductor chip is offset from the fourth semiconductor chip in the third direction, and
wherein the one or more dummy structures are spaced apart from the one or more third conductive structures in the third direction.

12. The semiconductor package of claim 11, wherein a level of each of the one or more third conductive structures is the same as a level of a surface of each of the one or more dummy structures.

13. The semiconductor package of claim 11, wherein the one or more dummy structures include a same metal material as the one or more third conductive structures.

14. The semiconductor package of claim 1, further comprising:
a molding film between the redistribution layer and the support substrate,
wherein the molding film is in contact with side surfaces of the one or more third chip pads.

15. A semiconductor package comprising:
a first semiconductor chip;
a second semiconductor chip spaced apart from the first semiconductor chip in a first direction;
a third semiconductor chip on the first semiconductor chip and the second semiconductor chip;
a first conductive structure on the first semiconductor chip, the first conductive structure extending in a second direction perpendicular to the first direction; and
a second conductive structure on the second semiconductor chip, the second conductive structure extending in the second direction,
wherein, in a plan view:
the first semiconductor chip and the second semiconductor chip are positioned along the first direction such that the first semiconductor chip is rotated 180 degrees along the first direction with respect to the second semiconductor chip, and
the third semiconductor chip is positioned on the first semiconductor chip and the second semiconductor chip such that the third semiconductor chip is rotated 90 degrees along the second direction with respect to the first semiconductor chip.

16. The semiconductor package of claim 15,
wherein the first semiconductor chip comprises a first chip pad,
wherein the second semiconductor chip comprises a second chip pad,
wherein the third semiconductor chip comprises a third chip pad,
the first chip pad and the second chip pad are in contact with the third semiconductor chip, and
a thickness of the third chip pad is larger than a thickness of the first chip pad and a thickness of the second chip pad.

17. The semiconductor package of claim 16, further comprising
a redistribution layer on the third semiconductor chip,
wherein the redistribution layer comprises a redistribution pattern that is in contact with the third chip pad.

18. The semiconductor package of claim 15, comprising:
a molding film covering the first semiconductor chip, the second semiconductor chip, and the third semiconductor chip,
wherein each of the first conductive structure and the second conductive structure comprises:
a seed pattern; and
a conductive pattern on the seed pattern, and
wherein the molding film is in direct contact with the conductive pattern.

19. A semiconductor package comprising:
a first semiconductor package; and
a second semiconductor package on the first semiconductor package,
wherein the first semiconductor package comprises:
a first redistribution layer;
a first semiconductor chip on the first redistribution layer;
a second redistribution layer on the first semiconductor chip; and
a first conductive structure between the first redistribution layer and the second redistribution layer, the first conductive structure extending in a first direction, and
the second semiconductor package comprises:
a support substrate;
a plurality of semiconductor chips stacked on the support substrate; and
a third redistribution layer spaced apart from the support substrate with the plurality of second semiconductor chips therebetween,
wherein each of the plurality of semiconductor chips stacked on the support substrate comprise:
a second semiconductor chip and a third semiconductor chip spaced apart from each other in a second direction parallel with a surface of the support substrate and perpendicular to the first direction; and
a fourth semiconductor chip on the second semiconductor chip and the third semiconductor chip, and
wherein the third redistribution layer comprises a redistribution pattern,
wherein a chip pad of the fourth semiconductor chip is in direct contact with the redistribution pattern,
wherein the semiconductor package further comprises one or more second conductive structures on the second semiconductor chip and the third semiconductor chip, and
wherein the fourth semiconductor chip is a memory chip.

20. The semiconductor package of claim 19.
wherein the first semiconductor chip is a logic chip, and
wherein the third semiconductor chip and the fourth semiconductor chip are memory chips.
